(19) United States
(12) Patent Application Publication
(10) Pub. No.: US 2009/0256165 A1
(43) Pub. Date: Oct. 15, 2009

(54) METHOD OF GROWING AN ACTIVE REGION IN A SEMICONDUCTOR DEVICE USING MOLECULAR BEAM EPITAXY

(76) Inventors: Katherine Louise SMITH, Oxford (GB); Mathieu Xavier Senes, Oxford (GB); Tim Michael Smeeton, Oxford (GB); Victoria Broadley, Oxon (GB); Stewart Edward Hooper, Oxford (GB)

Correspondence Address: MARK D. SARALINO ( SHARP );RENNER, OTTO, BOISSELLE & SKLAR, LLP, 1621 EUCLID AVENUE, 19TH FLOOR, CLEVELAND, OH, 44115, US

(21) Appl. No.: 12/102,261

(22) Filed: Apr. 14, 2008

(51) Int. Cl. H01L 21/20; H01L 33/00; H01S 5/323

(52) U.S. Cl. 257/94; 438/483; 372/43.01; 257/E21.09; 257/E33.049

(57) ABSTRACT

A method of making an (Al, Ga, In)N semiconductor device having a substrate and an active region is provided. The method includes growing the active region using a combination of (i) plasma-assisted molecular beam epitaxy; and (ii) molecular beam epitaxy with a gas including nitrogen-containing molecules in which the nitrogen-containing molecules dissociate at a surface of the substrate at a temperature which the active region is grown.

### TECHNICAL FIELD

The invention relates to devices fabricated in the (Al, Ga, In)N material system. The invention may be applied to, for example, a light-emitting diode, a laser diode or a spintronic device.

### BACKGROUND OF THE INVENTION

The (Al, Ga, In)N material system includes materials having the general formula AlₓGa_{y}In_{1-x-y}N where 0≦x≦1 and 0≦y≦1. In this application, a member of the (Al, Ga, In)N material system that has non-zero mole fractions of gallium and indium will be referred to as InGaN, a member that has zero mole fraction of indium and non-zero mole fractions of gallium and aluminium will be referred to as AlGaN. The term (In)GaN refers to InₓGa₁₋ₓN where 0≦x≦1 and therefore includes GaN as well as InGaN. Similarly (Al)GaN may refer to GaN or AlGaN, (In, Ga)N may refer to InN, GaN or InGaN and (Al, Ga, In)N may refer to AlN, GaN, InN, AlGaN, InGaN, AlInN or AlGaInN.

Any layer that provides the desired function of the device will herein be described as an active layer. For example in a blue laser diode, the active layers may be light-emitting InGaN quantum wells; in a quantum dot transistor the active layers would be the quantum dots where the charge is stored; or in the case of a spintronic device the active layers would be the layers where the spin is stored. The active layers may be composed of bulk layers, (i.e. do not demonstrate any quantum properties), or the active layers may be composed of quantum dots, quantum wires or quantum wells. The active layers may also consist of any combination of the above. The device may contain a plurality of active layers separated by layers with another material composition. For example, in a blue laser diode, GaN may separate the InGaN quantum well active layers. These separating layers will have a larger bandgap that those of the active layers. These layers will herein be referred to as barrier layers. The region of the device consisting of all the active layers and all the barrier layers will herein be referred to as the active region. By ‘fabricated in the (Al, Ga, In)N materials system’ is herein meant that at least one of the semiconductor layers is a (Al, Ga, In)N layer.

There is currently considerable interest in manufacturing devices in the (Al, Ga, In)N material system since devices in this system can emit light in the ultraviolet, infrared and entire visible wavelength range of the electromagnetic spectrum and has good potential for spintronic devices (Krishnamurthy et al, APL 83, 1761 (2003)). These devices may be grown by the method of molecular beam epitaxy. When growing devices in the (Al, Ga, In)N material system the molecular beam epitaxy method typically employs either ammonia gas or a plasma source with nitrogen gas to provide the active nitrogen. The use of ammonia with the molecular beam epitaxy method is described in S E Hooper et al, GB2323209A. The use of a plasma source for providing active nitrogen in molecular beam epitaxy (known as reactive ion molecular beam epitaxy, plasma-assisted molecular beam epitaxy, or molecular beam epitaxy with plasma) is described in T Moustakas et al, U.S. Pat. No. 5,633,192 and R. C. Powell et al in “Diamond, Silicon Carbide and related wide bandgap semiconductors”, vol. 162 edited by J. T. Glass, R. Messier and N. Fujimori (Material Research Society, Pittsburgh, 1990) pp. 525-530. Typically only one of these nitrogen sources is used when growing a device.

One example of the advantage of using plasma-assisted molecular beam epitaxy is that there is no dependence of the quantity of active nitrogen available at the growing surface on the temperature of the substrate. This is in contrast to molecular beam epitaxy with ammonia where ammonia molecules must dissociate on the growth surface in order for growth to occur and this dissociation is dependant on the sample temperature and the composition of the material being grown. (Mesrine et al (1998) Appl. Phys. Lett 72, 350 and Wick et al, J. Vac. Sci. Technol. B 23(3) May/June 2005). This may, for example, allow growth of (Al, Ga, In)N layers to be carried out at a lower temperature when using plasma-assisted molecular beam epitaxy than when using molecular beam epitaxy with ammonia. This may allow, for example, the growth of layers with higher indium content when using plasma-assisted molecular beam epitaxy than when using molecular beam epitaxy with ammonia. One example of the advantage of using molecular beam epitaxy with ammonia is that precise control of the stoichiometry of atoms arriving at the growth surface is not required, resulting in a larger window for the growth conditions. When using plasma-assisted molecular beam epitaxy, the growth window for the correct conditions for the growth of high quality material may be very narrow (see for example Skierbiszeski et al Appl. Phys. Lett. 88, 221108 (2006) and Heying et al Appl. Phys. Lett. 77, 2885 (2000)). This may result in poor sample uniformity and low device yields.

Each of the methods of plasma-assisted molecular beam epitaxy and molecular beam epitaxy with ammonia has been successfully used to produce devices in the (Al, Ga, In,)N material system. See for example M Kauer et al, Electon. Lett. 41, 23 (2005) for a laser diode grown by molecular beam epitaxy with ammonia, and Krishnamurthy et al, Appl. Phys. Lett. 83 1761 (2003), for a laser diode grown with plasma-assisted molecular beam epitaxy.

H. Tang et al Appl. Phys. Lett. 86, 121110 (2005) describes the use of InGaN quantum wells grown by plasma-assisted molecular beam epitaxy on top of the GaN grown using molecular beam epitaxy with ammonia. The roughness of the layer grown using molecular beam epitaxy with ammonia below the active region affects the growth of the active region. The layers grown by molecular beam epitaxy with ammonia do not from part of the active region.

M Senes et al Phys Rev B 75, 045314 (2007) states the growth of an active region using plasma-assisted molecular beam epitaxy on top of layers grown using molecular beam epitaxy with ammonia. The molecular beam epitaxy layers grown with ammonia are only used below the active region. All of the active InGaN layers and the GaN barrier layers that separate them are grown using plasma-assisted molecular beam epitaxy.

### SUMMARY OF THE INVENTION

According to an aspect of the invention, a method of making an (Al, Ga, In)N semiconductor device having a substrate and an active region is provided. The method includes growing the active region using a combination of (i) plasma-assisted molecular beam epitaxy; and (ii) molecular beam epitaxy with a gas including nitrogen-containing molecules in which the nitrogen-containing molecules dissociate at a surface of the substrate at a temperature which the active region is grown.

In accordance with a particular aspect, the method includes growing the active region using plasma-assisted molecular beam epitaxy, and molecular beam epitaxy with the gas including nitrogen-containing molecules, at different times.

According to another aspect, the method includes growing the active region using plasma-assisted molecular beam epitaxy, and molecular beam epitaxy with the gas including nitrogen-containing molecules, at the same time.

In accordance with another aspect, the active region comprises a plurality of layers, and the method comprises growing each of the plurality of layers using either of plasma-assisted molecular beam epitaxy, molecular beam epitaxy with the gas including nitrogen-containing molecules, or molecular beam epitaxy with both the plasma and the gas including nitrogen-containing molecules.

According to still another aspect, the method includes growing at least one of the plurality of layers using plasma-assisted molecular beam epitaxy, and growing at least another of the plurality of layers using molecular beam epitaxy with the gas including nitrogen-containing molecules.

In still another aspect, the method includes growing at least one other of the plurality of layers using molecular beam epitaxy with both the plasma and the gas including nitrogen-containing molecules.

In yet another aspect, the the plurality of layers includes active layers and barrier layers, with the barrier layers separating the active layers.

According to another aspect, a pair of adjacent active layers are separated by a barrier layer, and the method comprising growing at least one of the pair of active layers using plasma-assisted molecular beam epitaxy, and growing the barrier layer using molecular beam epitaxy with the gas including nitrogen-containing molecules.

In accordance with yet another aspect, a pair of adjacent active layers are separated by at least two barrier layers, and the method includes growing a first of the at least two barrier layers using plasma-assisted molecular beam epitaxy, and growing a second of the at least two barrier layers using molecular beam epitaxy with the gas including nitrogen-containing molecules.

According to another aspect, the gas including nitrogen-containing molecules comprises ammonia.

According to another aspect, the gas including nitrogen-containing molecules includes at least one of hydrazine, dimethylhydrazine, phenylhydrazine, tertiarybutylamine, isopropylamine, hydrogen azide, or ethylenediamine.

In accordance with another aspect, the plasma is supplied with gas comprising nitrogen.

In accordance with still another aspect, the active region is composed of at least one of InGaN, GaN, InN, AlGaN, AlInN or AlGaInN.

According to another aspect, the active layers within the active region are composed of at least one of InGaN, GaN, InN, AlGaN, AlInN and AlGaInN, and barrier layers within the active region are composed of at least one of InGaN, GaN, AlGaN, AlInN, AlN or AlGaInN.

In still another aspect, the active layers have a thickness of between 1 nm and 50 nm, and the barrier layers have a thickness of between 1 nm and 100 nm.

With still another aspect, the active layers have a thickness of between 1 nm and 10 nm, and the barrier layers have a thickness of between 1 nm and 10 nm.

According to another aspect, the semiconductor device is at least one of a light-emitting diode and a laser diode.

In accordance with another aspect, the active region comprises at least one active layer of AlₓGa_{y}In_{1-x-y}N quantum dots, where 0≦x≦1 and 0≦y≦1.

According to another aspect, the method includes growing the quantum dots using plasma-assisted molecular beam epitaxy.

With another aspect, the method includes growing a barrier layer separating adjacent active layers using molecular beam epitaxy with the gas including nitrogen-containing molecules.

In still another aspect, the quantum dots are grown at a temperature of between 300° C. and 1200° C.

According to another aspect, the quantum dots are grown at a temperature of between 550° C. and 750° C.

In accordance with another aspect, the quantum dots have a size wherein all three dimensions are each less than 50 nm.

According to another aspect, the quantum dots have a height less than 10 nm.

In still another aspect, an active layer within the active region comprises at least one of bulk material, quantum well or quantum wire structure.

According to another aspect, a light-emitting diode is manufactured in accordance with the steps described herein.

According to another aspect, a laser diode is manufactured in accordance with the steps described herein.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a schematic sectional view of the active region of a device in the AlGaInN material system as fabricated in the present invention.

FIG. 2 is a comparison of the average electroluminescence power from a wafer for a quantum dot light-emitting diode in the AlGaInN material system grown according to an embodiment of the present invention, and the average electroluminescence power from a wafer for a quantum dot light-emitting diode in the AlGaInN material system grown using only plasma-assisted molecular beam epitaxy during the growth of the active region of the device.

FIG. 3 is a comparison of the average electroluminescence power from a wafer for a quantum well light-emitting diode in the AlGaInN material system grown according to an embodiment of the present invention, and the average electroluminescence power from a wafer for a quantum well light-emitting diode in the AlGaInN material system grown using only plasma-assisted molecular beam epitaxy during the growth of the active region of the device.

FIG. 4 is a schematic sectional view of a quantum dot light-emitting device in the AlGaInN material system grown according to an embodiment of the present invention.

FIG. 5 is a schematic sectional view of a quantum dot laser diode device in the AlGaInN material system grown according to an embodiment of the present invention.

### DETAILED DESCRIPTION OF THE INVENTION

The present invention will now be described with reference to the drawings, in which like reference numerals are used to refer to like elements.

A device of the present invention may be grown on any suitable substrate; this includes but is not limited to any orientation of: sapphire, GaN, silicon or SiC.

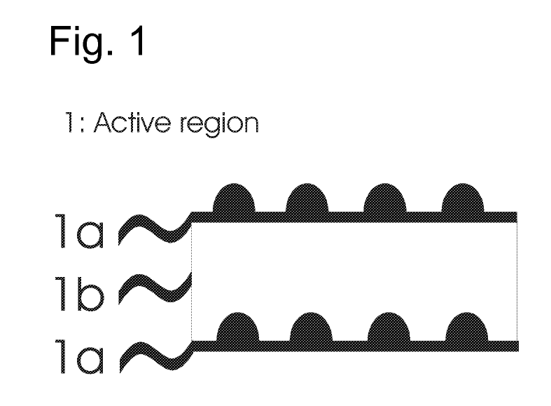

The present invention provides a semiconductor device fabricated in the (Al, Ga, In)N material system having an active region 1 of FIG. 1 that is grown using a combination of plasma-assisted molecular beam epitaxy and molecular beam epitaxy with ammonia. Each layer of the active region 1 of FIG. 1 is grown using either: only plasma-assisted molecular beam epitaxy, or only molecular beam epitaxy with ammonia, or molecular beam epitaxy with both plasma and ammonia. At least one layer of the active region 1 of FIG. 1 is grown using plasma-assisted molecular beam epitaxy and at least one layer of the active region 1 of FIG. 1 is grown using molecular beam epitaxy with ammonia. The active region 1 of FIG. 1 comprises at least one active layer 1a and at least one barrier layer 1b. Further pairs of active layers 1a and barrier layers 1b may be included in the active region to form an active region with multiple active layers.

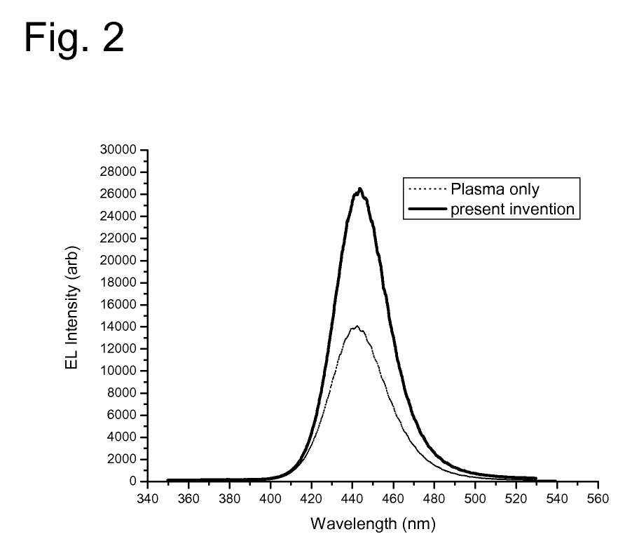

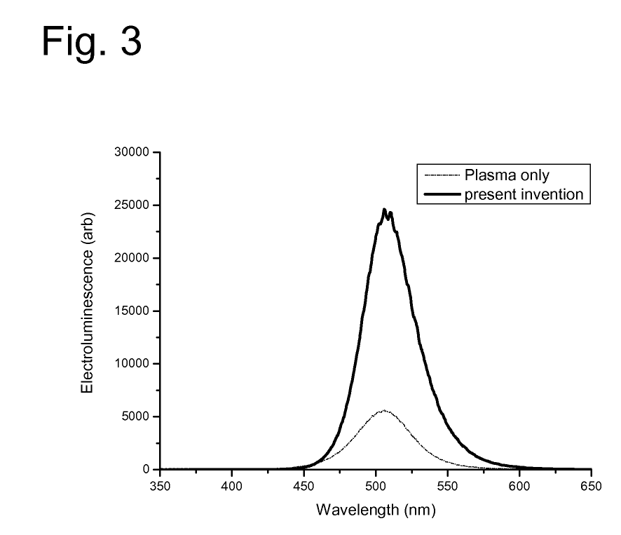

Growing at least part of the barrier layer using molecular beam epitaxy with ammonia has been found to significantly increase the average optical output power of a device. FIG. 2 shows the improvement in average output power from the quantum dot light-emitting diode devices of a wafer grown using the present invention compared with using only plasma-assisted molecular beam epitaxy during the growth of the active region. All other aspects of the growth were the same. FIG. 3 shows the improvement in average output power from a quantum well light-emitting diode devices of a wafer grown using the present invention compared with using only plasma-assisted molecular beam epitaxy during the growth of the active region. All other aspects of the growth were the same.

The active layers may be composed of InGaN, GaN, InN, AlGaN, AlInN, or AlGaInN. The active layers may be composed of bulk layers, (i.e. do not demonstrate any quantum properties), or the active layers may be composed of quantum dots, quantum wires or quantum wells. The active layers may also consist of any combination of the above. The active layers may have a thickness of between 1 nm and 50 nm. The active layers may have a thickness of between 1 nm and 10 nm. The composition and thickness of the second (and subsequent) active layers may be the same as the thickness and composition of the first (and subsequent) active layer(s). The composition and thickness of the second (and subsequent) active layers may be different from the thickness and composition of the first (and subsequent) active layer(s).

The first barrier layer may be a layer of InGaN, GaN, AlGaN, AlInN, AlN, or AlGaInN, such that the bandgap of the barrier layer is greater than the bandgap of the active layer. The barrier layer(s) may have a thickness of between 1 nm and 100 nm. The barrier layer(s) may have a thickness of between 1 nm and 10 nm. The composition and thickness of the second (and subsequent) barrier layers may be the same as the thickness and composition of the first (and subsequent) barrier layer(s). The composition and thickness of the second (and subsequent) barrier layers may be different from the thickness and composition of the first (and subsequent) barrier layer(s). Any of the active layers or barrier layers may be not intentionally doped, or they may be doped n-type or p-type.

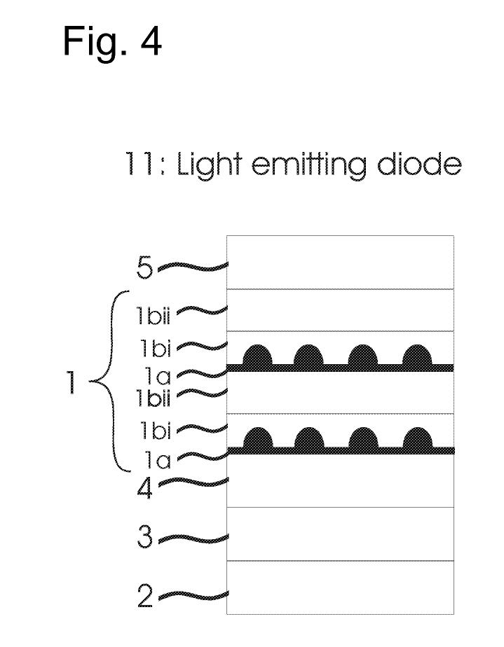

In a first embodiment of the present invention FIG. 4 is a schematic sectional view of a device 11 with a quantum dot active layer. In this embodiment the device is a light-emitting diode 11. The device is fabricated in the (Al, Ga, In)N material system.

The light-emitting diode 11 of FIG. 4 comprises a sapphire substrate 2. The light-emitting diode 11 of FIG. 4 may contain a buffer layer 3 disposed on the substrate layer 2. The buffer layer 3 may be any orientation of (Al, Ga)N. The buffer layer may be grown by any suitable method. In the light-emitting diode 11 of FIG. 4 the buffer layer is n-type GaN.

The light-emitting diode 11 of FIG. 4 may contain an n-type (Al, Ga, In)N layer 4 grown by molecular beam epitaxy. The (Al, Ga, In)N layer 4 may use ammonia as the source of active nitrogen and be grown at 860° C. Part of the (Al, Ga, In)N layer may be grown at a lower temperature of 640° C. The (Al, Ga, In)N layer may be annealed at 860° C.

The light-emitting-diode 11 of FIG. 4 may contain active layers of AlₓGa_{y}In_{1-x-y}N quantum dots 1a disposed on the (Al, Ga, In)N layers 4 or the barrier layers 1b. The AlₓGa_{y}In_{1-x-y}N quantum dot layers may have a composition wherein 0≦x≦1 and 0≦y≦1, therefore including GaN, InN, InGaN, AlGaN and AlGaInN. The quantum dot active layers may preferably have a composition wherein x=0 and 0.7<y<0.95. The quantum dots may have a size wherein all three dimensions are each less than 50 nm. The quantum dots may have a size wherein the height is less than 10 nm. The quantum dots may have a size wherein the height is between 1 nm and 5 nm. The quantum dots may be not intentionally doped, alternatively the quantum dots may be doped either n-type or p-type. The quantum dots may be grown using plasma-assisted molecular beam epitaxy. Any suitable gas containing nitrogen may be used in the plasma. The plasma is preferably supplied with nitrogen gas. The quantum dots may be grown at a temperature of between 300° C. and 1200° C. The quantum dots may preferably be grown at a temperature of between 550° C. and 750° C. The subsequent barrier layer 1b may be grown directly after the growth of the quantum dot layers. Alternatively there may be a growth interrupt where the supply of metal atoms to the surface is blocked. The growth interrupt may be between one second and one hour. The growth interrupt may be between one minute and five minutes.

The quantum dot active layers la may all be identical. The quantum dot active layers 1a may vary in composition. The quantum dot active layers 1a may vary in thickness.

The active region 1 of the light-emitting diode 11 of FIG. 4 may contain one or more (Al, Ga, In)N barrier layers 1b, each disposed over a respective quantum dot active layer 1a. The barrier layer 1bi may be grown using plasma-assisted molecular beam epitaxy. The bandgap of the barrier layer 1bi may be larger than the bandgap of the active layer 1a. The barrier layer 1bi may be grown at the same temperature as the quantum dot active layer 1a or it may be grown at a different temperature. The barrier layer 1bi may be not intentionally doped, or alternatively it may be doped n-type or p-type. If the quantum dot active layer has a composition of InₓGa₁₋ₓN where 0.05≦x≦0.3 the composition of the barrier layer may be GaN. The barrier layer 1bi may have a thickness of greater than 1 nm and less than 50 nm. The barrier layer 1bi may have a thickness of greater than 1 nm and less than 10 nm. The barrier layer 1bi may be annealed to a temperature between 800° C. and 1000° C. or the layer 1bi may be not annealed. The barrier layers 1bi may all be identical. The barrier layers 1bi may vary in composition. The barrier layers 1bi may vary in thickness. Barrier layer 1bii may be grown immediately after the barrier layer 1bi or there may be a growth-interrupt where the supply of metal atoms to the surface is blocked. The growth-interrupt may be between one second and one hour. The growth-interrupt may be between one minute and five minutes. The barrier layer 1bi may be omitted.

The active region 1 of the light-emitting diode 11 of FIG. 4 may further contain one or more (Al, Ga, In)N barrier layers 1bii where the active nitrogen is provided by ammonia, each layer 1bii is disposed over a layer 1 a or 1bi if present. The growth temperature of layer 1bii may be the same as either 1a or 1bi or may be different. The composition of the barrier layer 1bii may be the same composition as the barrier layer 1bi or may be different. The barrier layer 1bii may be not intentionally doped; alternatively it may be doped n-type or p-type. The barrier layer 1bii may have a thickness of greater than 1 nm and less than 50 nm. The barrier layer 1bii may have a thickness of greater than 1 nm and less than 10 nm. The barrier layer 1bii may be annealed to a temperature between 800° C. and 1000° C. or the layer may be not annealed. The barrier layers 1bii may all be identical. The barrier layers 1bii may vary in composition. The barrier layers 1bii may vary in thickness.

The (Al, Ga, In)N quantum dot active layer 1a and the (Al, Ga, In)N barrier layers 1bi and 1bii may be repeated in the sequence 1a, 1bi, 1bii, 1a, 1bi, 1bii or 1a, 1bii, 1a, 1bii to form an active region with multiple layers of quantum dots. This sequence may be continued to form more than two active layers of quantum dots 1a. Alternatively the active region may include only one active layer of quantum dots 1a.

The final (Al, Ga, In,)N barrier layers 1bi and 1bii may be omitted such that the final quantum dot active layer 1a is in direct contact with the p-type (Al, Ga, In,)N layer 5.

The light-emitting diode 11 of FIG. 4 may contain a (Al, Ga, In)N layer 5 disposed over the active region on the final quantum dot active layer 1a or the final barrier layer 1bii if present. The (Al, Ga, In)N layer 5 may be doped p-type, for example with magnesium. The thickness of the (Al, Ga, In)N layer 5 may be greater than 1 nm and less than 1 um. The thickness of the (Al, Ga, In)N layer 5 may be greater than 100 nm and less than 200 nm. The (Al, Ga, In)N layer 5 may be grown by molecular beam epitaxy using ammonia as the source of active nitrogen. The growth temperature may be greater than 500° C. and less than 1200° C. The growth temperature may be greater than 700° C. and less than 1000° C.

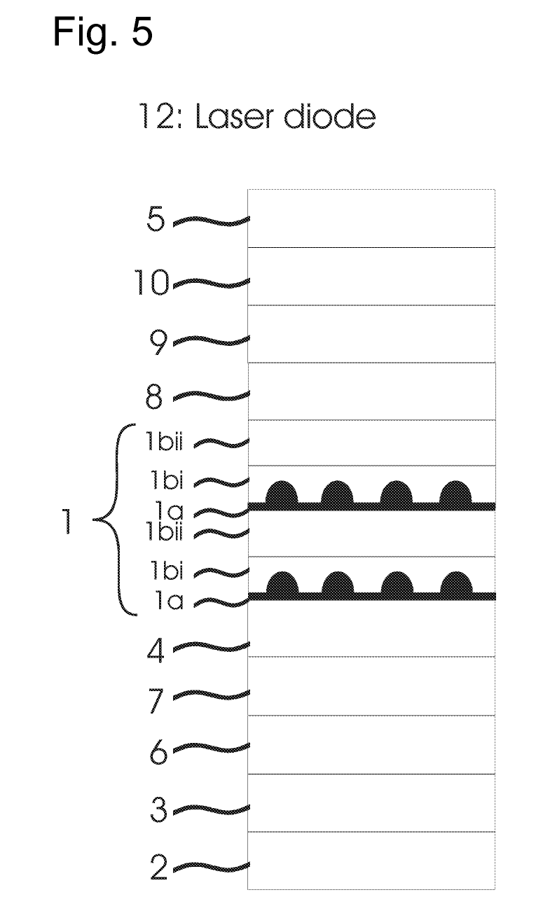

In a second embodiment the present invention may also be applied to the growth of a quantum dot laser diode. FIG. 5 is a schematic sectional view of a quantum dot laser diode 12 according to an embodiment of the present invention. Layers 2, 3, 4, 1a, 1bi, 1bii and 5 of the laser diode device are as already described for the light-emitting diode 11 of FIG. 4.

In addition the laser diode structure 12 of FIG. 5 may contain a first (Al, Ga, In)N cladding layer 6 disposed on the layer 4, a first (Al, Ga, In)N optical guiding layer 7 disposed on the first (Al, Ga, In)N cladding layer 6, a second (Al, Ga, In)N optical guiding layer 9 disposed over the active region 1 (on the final quantum dot layer 1a, or the final quantum dot capping layer 1bii if present) or the electron blocking layer 8 if present, and a second (Al, Ga, In)N cladding layer 10 disposed on the second GaN optical guiding layer 9.

In the laser diode 12 of FIG. 5, the first (Al, Ga, In)N cladding layer 6 and first (Al, Ga, In)N optical guiding layer 7 may be doped n-type with, for example, silicon. The second (Al, Ga, In)N optical guiding layer 9 and second (Al, Ga, In)N cladding layer 10 may be doped p-type with, for example, magnesium.

In the laser diode 12 of FIG. 5, the first cladding layer 6 may be an Al_{z}In_{y}Ga_{1-z-y}N layer with a composition wherein 0.01<z≦1 and 0≦y<1. The first cladding layer 6 may have a thickness greater than 100 nm and less than 2 μm and preferably has a thickness of approximately 1 μm. The second cladding layer 10, may also be an Al_{z}In_{y}Ga_{1-z-y}N layer with a composition wherein 0.01<z≦1 and 0≦y<1. The second (Al, Ga, In)N cladding layer 10 may have a thickness greater than 100 nm and less than 2 μm and preferably has a thickness of approximately 0.5 μm.

In the laser diode 12 of FIG. 5, the first (Al, Ga, In)N optical guiding layer 7 may have a thickness greater than 10 nm and less than 1 μm, and preferably has a thickness of approximately 160 nm. The first optical guiding layer 7, may be an Al_{z}In_{y}Ga_{1-z-y}N layer with a composition wherein 0.01>z≦1 and 0≦y<1. The second (Al, Ga, In)N optical guiding layer 9 may have a thickness greater than 10 nm and less than 1 μm, and preferably has thickness of approximately 160 nm. The second optical guiding layer 9, may be an Al_{z}In_{y}Ga_{1-z-y}N layer with a composition wherein 0.01<z≦1 and 0≦y<1.

In the laser diode 12 of FIG. 5, an (Al, Ga, In)N electron-blocking layer 8 may be disposed on the final quantum dot layer 1a, or the final quantum dot capping layer 1bii if present. The bandgap of the electron-blocking layer 8 may be greater than the bandgap of the barrier layers 1bi and 1bii. The thickness of the electron-blocking layer 8 may be greater than 1 nm and less than 100 nm. The thickness of the electron-blocking layer 8 may be greater than 1 nm and less than 10 nm. The composition of the AlₓGa₁₋ₓN electron-blocking layer 8 may be such that 0.01≦x<1. The composition of the AlₓGa₁₋ₓN electron-blocking layer 8 may be such that 0.05≦x≦0.2.

Layers 6, 7, 8, 9 and 10 of the laser diode in FIG. 5 may all be grown by molecular beam epitaxy using ammonia as the active nitrogen source, at a temperature greater than 600° C. and less than 1100° C. and preferably in the range greater than 850° C. and less than 1000° C. The growth temperatures may be different for the different layers.

The invention has been described with reference to embodiments having a quantum dot active region. However, the present invention is equally applicable to an active region with active layers consisting of bulk material, quantum wells or quantum wires. The active layers may also consist of any combination of the above.

The invention has been described with reference to embodiments of light-emitting diodes and laser diodes. However, the present invention of the method of growth of an active region in the (Al, Ga, In)N material system is not limited to these devices. The present invention may be extended to any device containing such an active region. This includes but is not limited to spin light-emitting diodes, solar cells, VCSELs, memory devices, transistors, quantum dot transistors, and spintronic devices.

This invention has been described with reference to molecular beam epitaxy with ammonia. This could be extended by one skilled in the art to any gas consisting of nitrogen-containing molecules that could be dissociated at the substrate surface at the temperature used for the growth of the (Al, Ga, In)N material, this includes but is not limited to hydrazine, dimethylhydrazine, phenylhydrazine, tertiarybutylamine, isopropylamine, hydrogen azide, ethylenediamine and any combination thereof.

Although the invention has been shown and described with respect to certain preferred embodiments, it is obvious that equivalents and modifications will occur to others skilled in the art upon the reading and understanding of the specification. The present invention includes all such equivalents and modifications, and is limited only by the scope of the following claims.

1. A method of making an (Al, Ga, In)N semiconductor device having a substrate and an active region, comprising:
growing the active region using a combination of (i) plasma-assisted molecular beam epitaxy; and (ii) molecular beam epitaxy with a gas including nitrogen-containing molecules in which the nitrogen-containing molecules dissociate at a surface of the substrate at a temperature which the active region is grown.

2. The method of claim 1, comprising growing the active region using plasma-assisted molecular beam epitaxy, and molecular beam epitaxy with the gas including nitrogen-containing molecules, at different times.

3. The method of claim 1, comprising growing the active region using plasma-assisted molecular beam epitaxy, and molecular beam epitaxy with the gas including nitrogen-containing molecules, at the same time.

4. The method of claim 1, wherein the active region comprises a plurality of layers, and the method comprises growing each of the plurality of layers using either of plasma-assisted molecular beam epitaxy, molecular beam epitaxy with the gas including nitrogen-containing molecules, or molecular beam epitaxy with both the plasma and the gas including nitrogen-containing molecules.

5. The method of claim 4, comprising growing at least one of the plurality of layers using plasma-assisted molecular beam epitaxy, and growing at least another of the plurality of layers using molecular beam epitaxy with the gas including nitrogen-containing molecules.

6. The method of claim 5, comprising growing at least one other of the plurality of layers using molecular beam epitaxy with both the plasma and the gas including nitrogen-containing molecules.

7. The method of claim 4, wherein the plurality of layers includes active layers and barrier layers, with the barrier layers separating the active layers.

8. The method of claim 7, wherein a pair of adjacent active layers are separated by a barrier layer, and the method comprising growing at least one of the pair of active layers using plasma-assisted molecular beam epitaxy, and growing the barrier layer using molecular beam epitaxy with the gas including nitrogen-containing molecules.

9. The method of claim 7, wherein a pair of adjacent active layers are separated by at least two barrier layers, and the method comprises growing a first of the at least two barrier layers using plasma-assisted molecular beam epitaxy, and growing a second of the at least two barrier layers using molecular beam epitaxy with the gas including nitrogen-containing molecules.

10. The method of claim 1, wherein the gas including nitrogen-containing molecules comprises ammonia.

11. The method of claim 1, wherein the gas including nitrogen-containing molecules includes at least one of hydrazine, dimethylhydrazine, phenylhydrazine, tertiarybutylamine, isopropylamine, hydrogen azide, or ethylenediamine.

12. The method of claim 1, wherein the plasma is supplied with gas comprising nitrogen.

13. The method of claim 1, wherein the active region is composed of at least one of InGaN, GaN, InN, AlGaN, AlInN or AlGaInN.

14. The method of claim 4, wherein active layers within the active region are composed of at least one of InGaN, GaN, InN, AlGaN, AlInN and AlGaInN, and barrier layers within the active region are composed of at least one of InGaN, GaN, AlGaN, AlInN, AlN or AlGaInN.

15. The method of claim 14, wherein the active layers have a thickness of between 1 nm and 50 nm, and the barrier layers have a thickness of between 1 nm and 100 nm.

16. The method of claim 15, wherein the active layers have a thickness of between 1 nm and 10 nm, and the barrier layers have a thickness of between 1 nm and 10 nm.

17. The method of claim 1, wherein the semiconductor device is at least one of a light-emitting diode and a laser diode.

18. The method of claim 17, wherein the active region comprises at least one active layer of AlₓGa_{y}In_{1-x-y}N quantum dots, where 0≦x<1 and 0≦y≦1.

19. The method of claim 18, comprising growing the quantum dots using plasma-assisted molecular beam epitaxy.

20. The method of claim 18, comprising growing a barrier layer separating adjacent active layers using molecular beam epitaxy with the gas including nitrogen-containing molecules.

21. The method of claim 18, wherein the quantum dots are grown at a temperature of between 300° C. and 1200° C.

22. The method of claim 21, wherein the quantum dots are grown at a temperature of between 550° C. and 750° C.

23. The method of claim 18, wherein the quantum dots have a size wherein all three dimensions are each less than 50 nm.

24. The method of claim 18, wherein the quantum dots have a height less than 10 nm.

25. The method of claim 1, wherein an active layer within the active region comprises at least one of bulk material, quantum well or quantum wire structure.

26. A light-emitting diode manufactured in accordance with the steps of claim 1.

27. A laser diode manufactured in accordance with the steps of claim 1.
